(19) United States
(12) Patent Application Publication
(10) Pub. No.: US 2010/0178568 A1
(43) Pub. Date: Jul. 15, 2010

(54) Process for producing carbon nanostructure on a flexible substrate, and energy storage devices comprising flexible carbon nanostructure electrodes

(75) Inventors: Husnu Emrah Unalan, Beysukent/Ankara (TR); Nalin Lalith Rupesinghe, Cambridge (GB); Gehan Amaratunga, Cambridge (GB)

Correspondence Address: WARE FRESSOLA VAN DER SLUYS & ADOLPHSON, LLP, BRADFORD GREEN, BUILDING 5, 755 MAIN STREET, P O BOX 224, MONROE, CT, 06468, US

(73) Assignee: Nokia Corporation

(21) Appl. No.: 12/319,933

(22) Filed: Jan. 13, 2009

(51) Int. Cl. H01M 6/18; H01M 10/00; H01M 4/02; H01M 4/58; H01M 4/52; H01M 6/04; C23C 16/26

(52) U.S. Cl. 429/317; 429/122; 429/209; 429/220; 429/221; 429/200; 427/122; 427/249.1; 361/504; 977/742

(57) ABSTRACT

An energy storage device structure comprises a first electrode layer, an electrolyte layer and a second electrode layer. At least one of the electrode layers comprise a metallic base layer and a layer of carbon nanotubes grown on the base layer, the carbon nanotube layer being arranged to face the electrolyte layer. The structure has much larger width and length than thickness, so it is rolled up or folded and then hermetically sealed to form an energy storage unit. The layer of carbon nanotubes is grown on the metallic base layer by a chemical vapor deposition process at a temperature no higher than 550° C. The carbon nanotubes in the carbon nanotube layer are at least partially aligned in a direction that is perpendicular to the surface of the metallic base layer.

### DISCLOSURE OF JOINT RESEARCH AGREEMENT

The claimed invention was made under a joint research agreement between Nokia Corporation, Finland, and University of Cambridge, United Kingdom. The joint research agreement was in effect before the date the claimed invention was made, and the claimed invention was made as a result of activities undertaken within the scope of the joint research agreement.

### TECHNICAL FIELD

This disclosure relates to a process for producing carbon nanostructure, especially carbon nanotubes, on a flexible metallic substrate. Also the disclosure relates to energy conversion and storage devices, such as batteries and supercapacitors, having charge collectors made with the carbon nanotubes grown on the flexible substrate.

### BACKGROUND ART

The ever-increasing demand for portable electronic devices motivates technological improvements in energy conversion and storage units, such as batteries, used in these devices. In developing the energy conversion and storage units, lightweight construction, long lifetime, high power density and flexibility to meet various design and power needs are important factors to consider. Examples of the energy conversion and storage units suitable for portable electronic devices include lithium ion batteries, lithium metal batteries, supercapacitors, etc.

Lithium ion batteries are currently one of the most popular types of solid-state batteries for portable electronic devices, with one of the best energy-to-weight ratios, no memory effect, and a slow loss of charge when not in use. The three primary functional components of a lithium ion battery are anode, cathode and electrolyte, for which a variety of materials may be used. Commercially, the most popular material for the anode is graphite. The cathode may be made with an intercalation lithium compound such as lithium cobalt oxide, lithium iron phosphate, lithium manganese oxide, etc.

Lithium metal batteries, or lithium metal polymer batteries, are rechargeable batteries that evolved from lithium-ion batteries. A lithium-metal battery structure comprises a lithium metal anode, a polymer composite electrolyte and a cathode. Lithium metal batteries can be produced by stacking thin films of these materials together. The resulting device structure is flexible, tough, and durable. The advantages of lithium metal polymer structure over the traditional lithium ion design include lower cost of manufacturing and being more robust to physical damage.

Supercapacitors resemble a regular capacitor with the exception that it offers very high capacitance in a small package. Energy storage is by means of static charge rather than of an electro-chemical process that is inherent to the batteries. Applying a voltage differential on the positive and negative plates charges the supercapacitor. Whereas a regular capacitor consists of conductive foils and a dry separator, the supercapacitor crosses into battery technology by using electrodes and electrolyte that are similar to lithium ion/lithium metal batteries. Hence, a combination of battery and supercapacitor is of great interest for achieving high energy density and power density. For enhanced charge storage capacity, electrode materials suitable for the battery/supercapacitor combination should have a high surface area.

Recently, nanostructured materials are being used in rechargeable batteries. Nanostructured carbon, such as carbon nanotubes, carbon nanowires, carbon nanohorns and carbon nano-onions are being contemplated for replacing graphite. In the description that follows, carbon nanotube (CNT) is selected as a specific example of the nanostructured materials. However, it is to be understood that the scope of the disclosure is not limited by any specific substance in any particular examples or embodiments.

CNT is a highly crystallized tubular structure of carbon. One single nanotube is about a few nanometers in diameter and up to a hundred microns long. Millions of nanotubes together may form a cluster of macroscopic material that is practically useful. CNTs have several important properties, including high mechanical strength, high electrical conductivity, high thermal conductivity, being able to carry high current densities, chemically resistant to attacks by strong acids or alkali, and, collectively, extremely high surface area.

CNTs may be grown from a smooth substrate to form a layer of densely packed, vertically aligned CNT pile (morphologically similar to a pile of fiber on a carpet). Such a well-arranged nanostructure has an extremely high surface area. Used in batteries or supercapacitors, the CNT layer can store significantly more electrical charge (e.g. lithium ions) than those electrodes made with conventional materials such as graphite. The use of the CNT technology not only enables the energy storage unit to provide long and stable power as in a conventional battery, but also enables the quick burst of high energy that is typical of a supercapacitor.

In this disclosure, a process for producing highly packed and vertically aligned CNT structure on a flexible substrate is described. The flexible CNT structure thus resulted can be directly used in making batteries and supercapacitors. The process is suitable for mass productions of the nanostructured carbon material and mass production of the energy storage units comprising the nanostructured carbon material.

### SUMMARY OF THE INVENTION

In a first aspect of the invention, a device structure is provided. The device structure comprises a first sheet of a conductive material; a sheet of a substance disposed on the first sheet of the conductive material, the substance being able to conduct free ions therein; and a second sheet of same or different conductive material disposed on the sheet of the substance. At least one of the first sheet and second sheet comprises a metal foil layer and a carbon nanotube layer, the carbon nanotube layer being arranged to face the sheet of the substance. The carbon nanotube layer is directly grown on the metal foil layer.

In the device, the first sheet, the sheet of the substance and the second sheet may form a multi-layered stack, and the device may further comprise a first insulating sheet and a second insulating sheet disposed on outer surfaces of the multi-layered stack, respectively.

The device may have much larger width and length than thickness. The device may be rolled up or folded and then hermetically sealed to form an energy storage unit. The energy storage unit may be a rechargeable battery or a capacitor, and the first and the second conductive sheets are configured to engage with an external energy source or drain.

In the device, the metal foil may be one of the following: aluminum, copper, iron, and alloys of aluminum, copper or iron. The metal foil may have a thickness of 5 to 100 microns.

The carbon nanotube layer is directly grown on the metal foil by a process that comprises: coating a catalyst on a surface of the metal foil by low temperature evaporation of the catalyst; annealing the catalyst coated metal foil in ammonia gas at a first temperature; and growing the carbon nanotubes directly on the catalyst coated surface of the metal foil in a hydrocarbon gas atmosphere at a second temperature. The first temperature is lower than the second temperature and the second temperature is no higher than 550° C.

In the device, the sheet of the substance may comprise a sheet of microperforated plastic film and an electrolyte disposed on surfaces of the plastic film. The microperforated plastic film may be a membrane made of polyethylene (PE)-polypropylene (PP). The electrolyte may a composite of a lithium salt and one of the following polymers: ethylene carbonate (EC), diethylene carbonate (DC) and propylene carbonate (PC). Alternatively, the electrolyte may be a room temperature ionic liquid electrolyte. The room temperature ionic liquid electrolyte may comprise 1-butyl, 3-methylimidazolium chloride ([BMIM] [Cl]), 1-25% of cellulose and a lithium salt.

The carbon nanotubes in the carbon nanotube layer are at least partially aligned in a direction. The direction may be at least nearly perpendicular to the surface of the metal foil.

In a second aspect of the invention, a process for forming a layer of carbon nanotubes on a flexible metal foil is provided. The process comprises coating a catalyst on a surface of the metal foil by low temperature evaporation of the catalyst; annealing the catalyst coated metal foil in ammonia gas at a first temperature; and growing the carbon nanotubes directly on the catalyst coated surface of the metal foil in a hydrocarbon gas atmosphere at a second temperature. The first temperature is lower than the second temperature and the second temperature is no higher than 550° C.

In the process, the metal foil may be one of the following: aluminum, copper, iron, and alloys of aluminum, copper or iron. The metal foil may have a thickness of 5 to 100 microns. The catalyst may comprise one of the following: iron, nickel and cobalt.

The catalyst may have a particle size of no more than 50 nanometers. The carbon nanotubes may be grown to a length of 10 to 100 microns. The carbon nanotubes grown on the metal foil may be at least partially aligned in a direction. The direction may be at least nearly perpendicular to the surface of the metal foil. The process is carried out in a chemical vapor deposition system.

In a third aspect of the invention, a method is provided. The method comprises providing a first sheet of a conductive material; disposing a sheet of a substance on the first sheet of the conductive material, the substance being able to conduct free ions therein; and disposing a second sheet of same or different conductive material on the sheet of the substance. At least one of the first sheet and the second sheet comprises a metal foil layer and a carbon nanotube layer, the carbon nanotube layer being arranged to face the sheet of the substance. The carbon nanotube layer is directly grown on the metal foil layer.

The first sheet, the sheet of the substance and the second sheet may form a multi-layered stack, and the method further comprises disposing a first insulating sheet and a second insulating sheet on outer surfaces of the multi-layered stack, respectively. The multi-layered stack may have much larger width and length than thickness, and the method further comprises rolling up or folding the multi-layered stack; and hermetically sealing the rolled-up or folded multi-layered stack to form an energy storage unit. The energy storage unit may be a rechargeable battery or a capacitor, and the first and the second conductive sheets are configured to engage with an external energy source or drain.

In the method above, the carbon nanotube layer may be grown directly on the metal foil layer by a process that comprises: coating a catalyst on a surface of the metal foil by low temperature evaporation of the catalyst; annealing the catalyst coated metal foil in ammonia gas at a first temperature; and growing the carbon nanotubes directly on the catalyst coated surface of the metal foil in a hydrocarbon gas atmosphere at a second temperature. The first temperature is lower than the second temperature and the second temperature is no higher than 550° C. The process for growing the carbon nanotube layer may be carried out in a chemical vapor deposition system.

### BRIEF DESCRIPTION OF THE DRAWINGS

The features and advantages of the invention will become apparent from a consideration of the subsequent detailed description presented in connection with accompanying drawings, in which:

FIG. 1 is a schematic illustration of a layer of aligned CNTs grown on a flexible metal foil;

FIG. 2 is a Raman scattering spectrum of the CNTs grown on an Al foil;

FIG. 3 is a schematic illustration of a thin film energy storage device structure;

FIGS. 4a and 4b illustrate the charging and discharging mechanisms of a lithium ion battery, in which the anode comprises CNT nanostructure;

FIG. 5 is a schematic illustration a lithium metal battery in which the cathode comprises CNT nanostructure;

FIG. 6 is a schematic illustration of a supercapacitor in which one or both of the electrodes comprise CNT nanostructure;

FIG. 7 is an example of a thin film lithium metal/lithium ion battery core that is produced by rolling a multi layered thin film stack; and

FIG. 8 is cyclic voltammetry data of a supercapacitor made with CNTs grown on flexible Al foil compared with that made with graphite.

### DETAILED DESCRIPTION

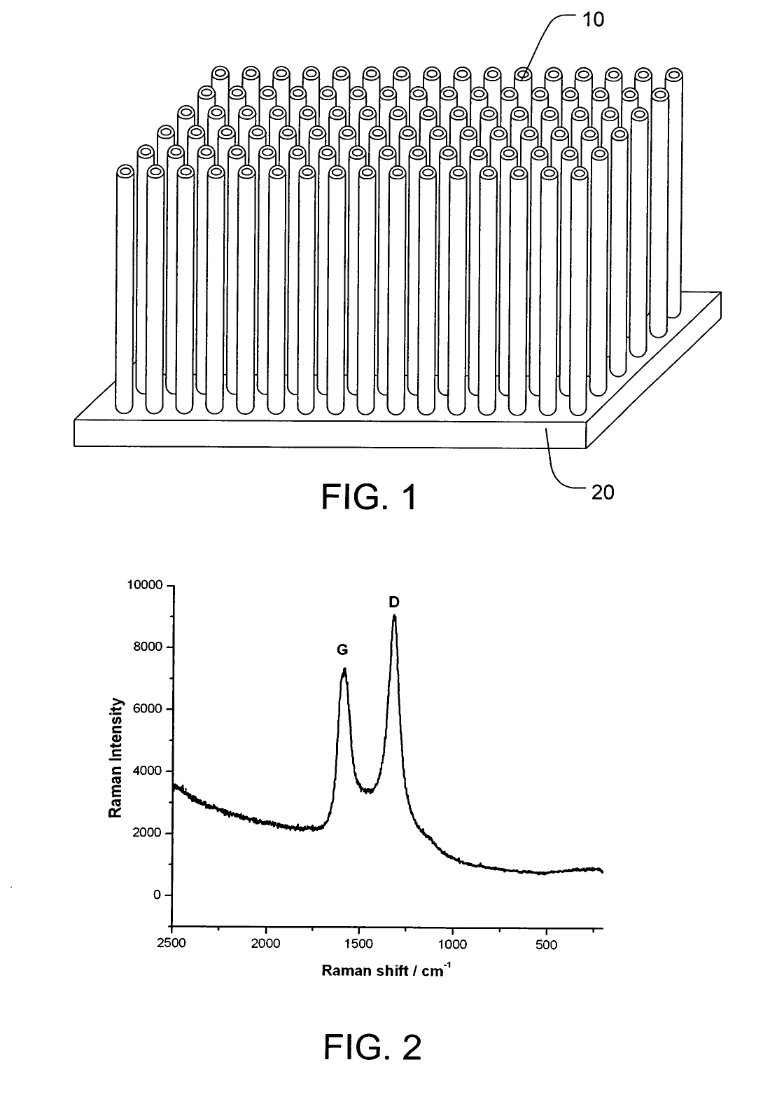

FIG. 1 shows, schematically, a sheet of densely packed, vertically aligned carbon nanotubes 10 grown on a metal foil substrate 20. For achieving a maximum surface area, ideally a CNT sheet should have CNTs densely packed (one nanotube next to another with gaps between the nanotubes about the same size as the Li ion) and aligned perpendicular or nearly perpendicular to the surface of the substrate. Preferably, the carbon nanotubes are multiwalled carbon nanotubes. By directly growing the CNTs on a flexible conductive substrate, the CNTs do not have to be removed from the substrate for the applications, and the substrate can be directly used in those energy storage devices where the components thereof must be folded or rolled for minimizing the overall volume of the devices. This not only simplifies the manufacturing procedure but also makes it more cost effective.

The growth of the CNTs on the substrate is preferably carried out by a low temperature plasma enhanced chemical vapor deposition (PECVD) method. The deposition process utilizes nanoparticles of a metal catalyst to react with a hydrocarbon gas. In the deposition process, the catalyst decomposes the hydrocarbon gas to produce carbon and hydrogen. The carbon dissolves into the particle and precipitates out from its circumference as the carbon nanotube. Thus, the catalyst acts as a ‘template’ from which the carbon nanotube is formed, and by controlling the catalyst particle size and reaction time, one can tailor the nanotube diameter and length respectively to suit. CNTs, in contrast to solid carbon nanowires, tend to form when the catalyst particle is ˜50 nm or less.

Typically, the CVD growth temperature is higher than 700° C., which prohibits the use of many thin and flexible substrates. In the present invention, aligned carbon nanotubes are grown directly on thin and flexible metal foils at a temperature no higher than 550° C.

A metal foil is cut to size and cleaned consecutively by acetone and by isopropanol in an ultrasonic bath for 5 minutes each, followed by rinsing with de-ionized water and drying in a nitrogen flow. The metal foil may be made of various metals or alloys such as Al, Cu or stainless steel, preferably Al or Cu. Conventional metal foils can be manufactured by various methods known in the art, so normally these foils are commercially available. The thickness of the metal foil can be from 5 to 100 μm so long as it has sufficient mechanical strength and desired flexibility. Impurities in the metal foil should be sufficiently low so that they do not inhibit the CNT growth and contaminate the growth equipment.

Before the CNT growth, a layer of the catalyst is deposited on the surface of the substrate by low temperature evaporation technique in a DC sputtering system (e.g. at a base pressure of 2.1×10⁻⁶ atm, 20 sccms of argon flow with 50 W plasma power for 20 seconds). The thickness of the catalyst layer is less than 5 nanometers. Suitable catalysts include iron (Fe), nickel (Ni) and cobalt (Co). CNT growth is carried out in a quartz vacuum chamber of a chemical vapor deposition (CVD) system. One example of a commercially available CVD system is Aixtron Nanoinstruments Plasma Enhanced Chemical Vapor Deposition system. One or more catalyst-coated substrates are placed on a resistively heated graphite stage in the quartz chamber. Growth temperature is controlled by a thermocouple attached to the surface of the graphite stage. The metal foil substrates are heated up in an ammonia gas (NH₃) atmosphere to 450° C. and annealed at 450° C. for a predetermined period.

After the annealing, the temperature of the graphite stage is ramped up to 520° C. (for Al foil) or to 540° C. (for Cu foil) and acetylene (C₂H₂) was supplied as the carbon feedstock for the CNT growth. After the CNTs have grown to the desired length, the substrates are cooled to room temperature. Nitrogen gas (N₂) was supplied at the end of the growth. It is observed that 15 minutes of growth time may yield 30 to 40 μm long CNTs on an Al foil and 70-80 μm long CNTs on a Cu foil.

The as-grown CNT samples are then inspected by a Raman scattering spectroscopy. FIG. 2 shows a Raman scattering spectrum of the CNTs grown on an Al foil. The multiwalled nanotube structure is confirmed by the D and G bands in the spectrum.

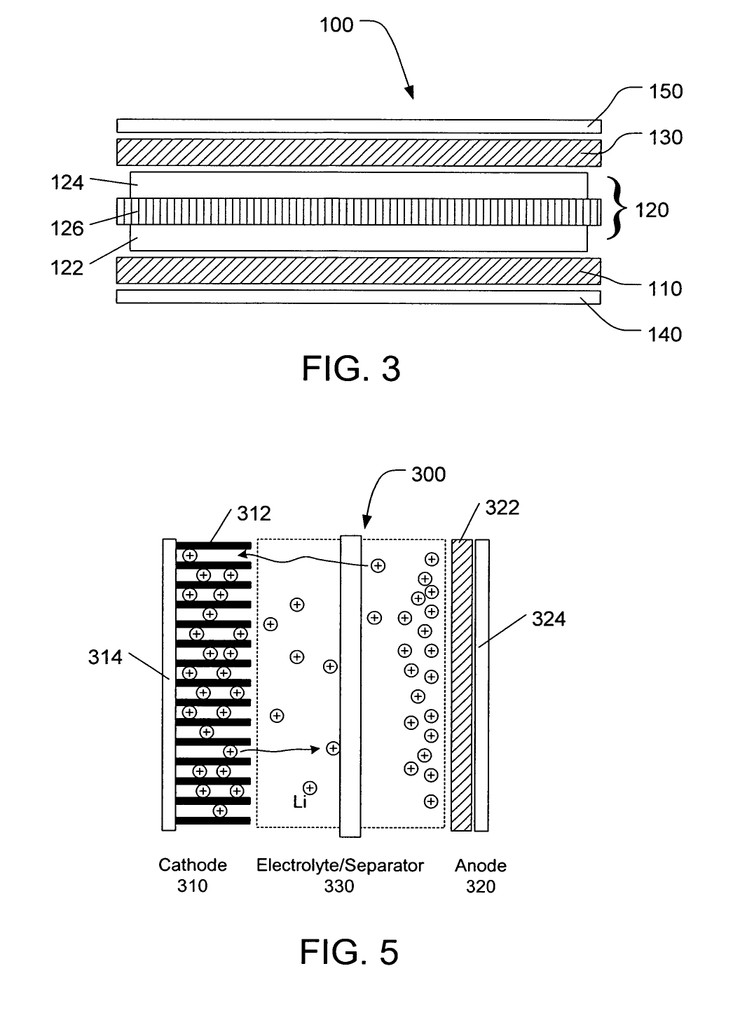

Referring now to FIG. 3, a basic structure of a multi-layered energy storage device 100 comprises a first sheet of a conductive material 110, a sheet of a free ion conductive electrolyte/separator 120 disposed on the first sheet of the conductive material 110, and a second sheet of same or different conductive material 130 disposed on the sheet of the electrolyte 120. The first sheet 110, the sheet of the electrolyte 120 and the second sheet 130 form a basic multi-layered stack. The first and the second conductive sheets 110 and 130 are used as electrodes (anode and cathode, respectively).

The sheet of the electrolyte 120 may have different constructions. One example is that it comprises a separator layer 126. The separator 126 may be a thin sheet of micro-perforated plastic such as a polymer-based membrane, e.g. a 25 μm thick polyethylene (PE)-polypropylene (PP) (trade name CELGARD), or any suitable material such as paper. As the name implies, the separator is an ionic conductor but electric insulator that separates the first and the second conductive sheets while allowing the free ions to pass through. The separator 126 may further filled with or applied thereon an electrolyte (electrolyte layers 122 and 124 on both surfaces of the separator layer 126 are shown). An electrolyte is any substance containing free ions that behaves as an electrically conductive medium. Besides conventional organic electrolytes such as ethylene carbonate (EC), diethylene carbonate (DC) and propylene carbonate (PC), a room temperature ionic liquid (RTIL) electrolyte, for example, 1-butyl, 3-methylimidazolium chloride ([BMIM][Cl]) composing of 1-25% cellulose and a lithium salt, can be preferably used as a gel electrolyte for the fabrication of a fully solid state rechargeable battery. The RTIL gels are non-flammable, flexible and environmentally safe.

The first conductive sheet 110 and/or the second conductive sheet 130 may further comprise a metal foil base layer (acting as a charge collector) and a charge storage or charge supply layer. The charge storages layer may be composed of the carbon nanotube structure and it may be grown on the base layer as shown in FIG. 1. The charge supply layer may be composed of a compound, such as a lithium metal oxide, or lithium metal, depending on the type of the device. In the device structure, the charge storage layer and charge supply layer face the electrolyte layer 120. The device structure 100 further comprises a first insulator sheet 140 and a second insulator sheet 150 disposed on outer surfaces of the multiplayer stack.

Following is a brief description of various energy storage devices according to the present invention.

1. Lithium ion Battery Structure

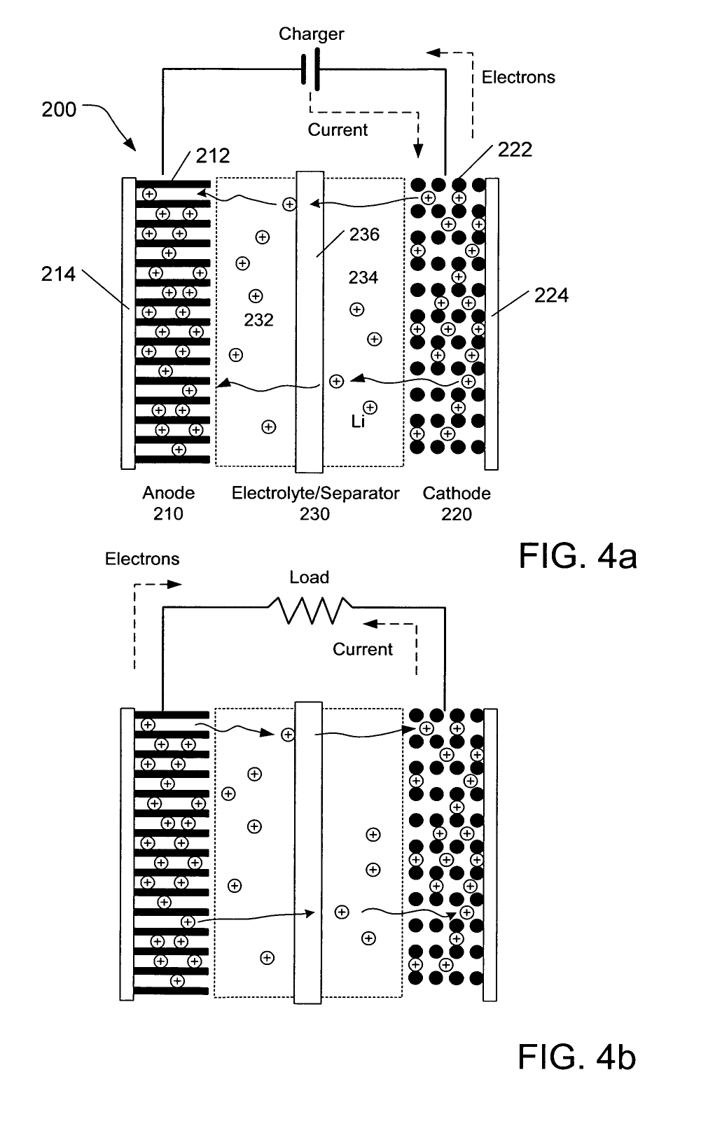

FIGS. 4a and 4b show respectively the charge and discharge mechanisms of a lithium ion battery 200 according to the present invention. Inside the battery 200, the anode 210 (negative electrode) is made of a CNT layer 212 directly grown on a metal foil substrate 214, and the cathode 220 (positive electrode) is made of a lithium metal oxide layer 222 and a metal foil charge collector layer 224. Examples of lithium metal oxide include lithium cobalt oxide (LiCoO₂), lithium manganese oxide (LiMnO₄) and lithium nickel oxide (LiNiO₂). A more advanced cathode may be made with LiFePO₄. When the battery is charged, i.e. electrons are supplied to the anode, positively charged lithium ions migrate from the cathode 220 and intercalate into the CNT layer 212 (FIG. 4a). When the battery is discharged, positive lithium ions move back from the anode 210 to replace the missing charges in the cathode 220 (FIG. 4b). In either direction, the lithium ions diffuse through the electrolyte/separator 230, which is composed of a separator layer 236 and electrolyte layers 232 and 234.

2. Lithium Metal Battery Structure

FIG. 5 shows a structure of a rechargeable lithium metal battery 300 according to the present invention. Inside the battery 300, the cathode 310 is made of a CNT layer 312 directly grown on a metal foil substrate 314, and the anode 320 is made of a layer of lithium metal 322 and a metal foil charge collector layer 324. When charging or discharging the battery, the lithium ions diffuse through the electrolyte/separator 330.

3. Supercapacitor Structure and Combined Battery/Supercopacitor

Like regular capacitors, supercapacitors use the surface of the conductive plates for charge storage. The higher the surface area, generally the higher charge storage capacity. Therefore, high-surface-area CNTs are inherently suitable for use in the supercapacitors. In fact, many of the same materials as used in lithium metal/lithium ion batteries may be used in superpacitors.

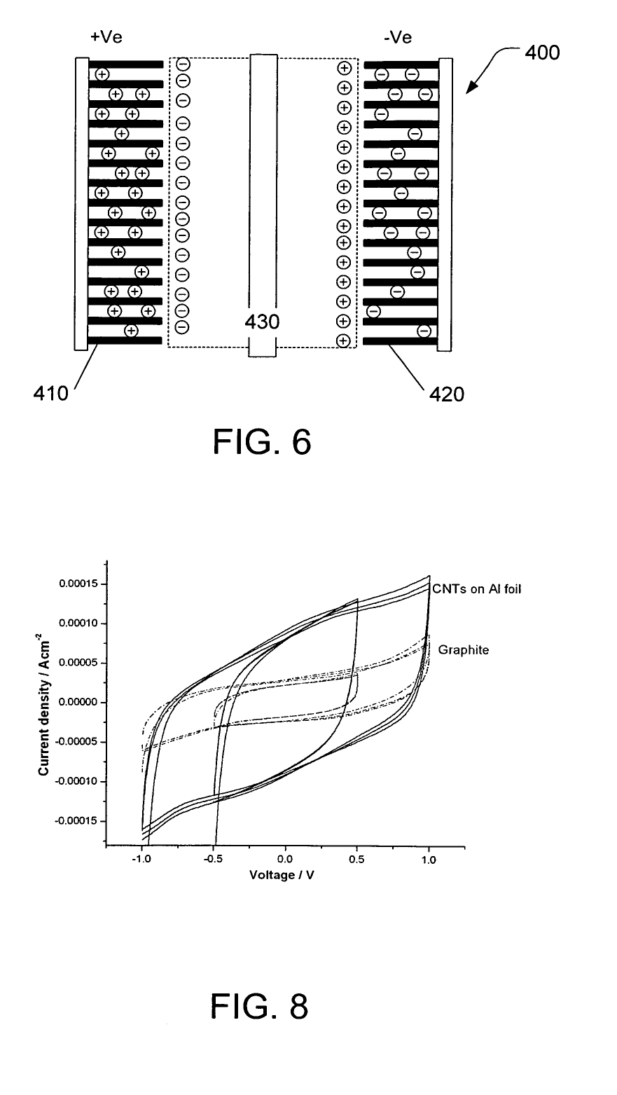

FIG. 6 shows schematically a supercapacitor structure 400 according to the present invention. The structure comprises charge plates 410 and 420, separated by a separator/electrolyte 430. One or both of the charge plates 410 and 420 are composed of CNTs grown on a flexible metal foil for providing extremely high surface areas.

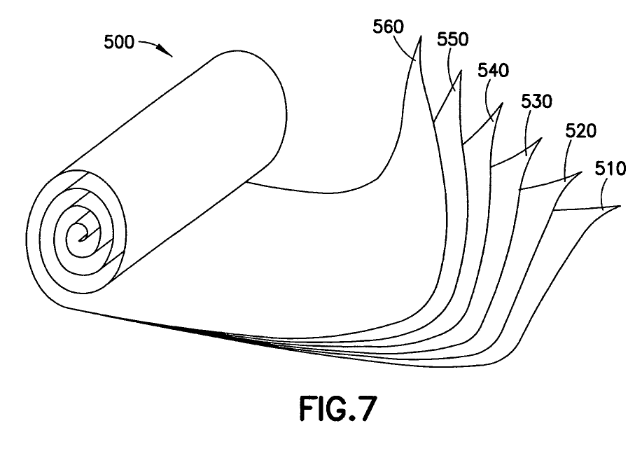

FIG. 7 shows a particular example of the multi-layered energy storage structure of FIG. 3, in which, according to the present invention, at least one of the layers is a layer of CNTs grown on a metal foil. The structure 500 comprises a first layer of insulator 510, a metal foil charge collector 520, a layer of Li metal foil or lithium metal oxide 530, a layer of separator integrated with solid state lithium electrolyte 540 as mentioned above, a layer of metal foil 550 with CNT structure directly grown thereon, wherein the CNT layer facing the electrolyte, and a second layer of insulator 560. The width and length of the stack are much larger than its thickness.

A practical energy storage unit is made by folding or rolling up the stacked sheets. For this example, the multi layer stack 500 is rolled into a cylindrical shape. The roll is then hermetically sealed. Preferably, the fabrication process takes place in an inert gas environment that is oxygen-free (e.g. oxygen level not exceeding 5 ppm).

FIG. 8 is exemplary cyclic voltammetry data of a supercapacitor made with CNTs grown on flexible Al foil, compared with the same supercapacitor made with a graphite plate. The data show that the supercapacitor made with the CNT layer can achieve much higher discharge current density.

In summary, the present invention provides a process for growing CNT nanostructure on a flexible metal foil substrate. The CNT nanostructure can be directly used in fabrication energy conversion and storage units suitable for portable electronic devices. Due to the extremely large surface area, aligned CNTs on a metal foils is very advantageous over traditional graphite electrodes.

The application can also be extended to photovoltaic devices and fuel cells which use the same electrode structure. In addition, other carbon nanostructured materials such as carbon nanohorns and carbon nano-onions can also be deposited directly on such flexible metal substrates. This process can further enable the roll-to-roll fabrication of nanostructured electrodes for industrialized mass production.

It is to be understood that the above-described arrangements are only illustrative of the applications of the principles of the teachings hereof. In particular, it should be understood that although only a few examples have been shown, the teachings hereof are not restricted to those examples. Numerous modifications and alternative arrangements may be devised by those skilled in the art without departing from the scope of the present disclosure.

1. A device, comprising:
a first sheet of a conductive material;
a sheet of a substance disposed on the first sheet of the conductive material, the substance being able to conduct free ions therein; and
a second sheet of same or different conductive material disposed on the sheet of the substance, wherein at least one of the first sheet and second sheet comprises a metal foil layer and a carbon nanotube layer, the carbon nanotube layer being arranged to face the sheet of the substance, and wherein the carbon nanotube layer is directly grown on the metal foil layer.

2. The device of claim 1, wherein the first sheet, the sheet of the substance and the second sheet form a multi-layered stack, and the device further comprises a first insulating sheet and a second insulating sheet disposed on outer surfaces of the multi-layered stack, respectively.

3. The device of claim 2, wherein the device has much larger width and length than thickness, the device is rolled up or folded and then hermetically sealed to form an energy storage unit.

4. The device of claim 3, wherein the energy storage unit is a rechargeable battery or a capacitor, and the first and the second conductive sheets are configured to be engaged with an external energy source or drain.

5. The device of claim 1, wherein the metal foil is one of the following: aluminum, copper, iron, and alloys of aluminum, copper or iron.

6. The device of claim 1, wherein the metal foil has a thickness of 5 to 100 microns.

7. The device of claim 1, wherein the carbon nanotube layer is directly grown on the metal foil by a process that comprises:
coating a catalyst on a surface of the metal foil by low temperature evaporation of the catalyst;
annealing the catalyst coated metal foil in ammonia gas at a first temperature; and
growing the carbon nanotubes directly on the catalyst coated surface of the metal foil in a hydrocarbon gas atmosphere at a second temperature, wherein the first temperature is lower than the second temperature and the second temperature is no higher than 550° C.

8. The device of claim 1, wherein the sheet of the substance comprises a sheet of microperforated plastic film and an electrolyte disposed on surfaces of the plastic film.

9. The device of claim 8, wherein the microperforated plastic film is a membrane made of polyethylene (PE)-polypropylene (PP).

10. The device of claim 8, wherein the electrolyte is a composite of a lithium salt and one of the following polymers: ethylene carbonate (EC), diethylene carbonate (DC) and propylene carbonate (PC).

11. The device of claim 8, wherein the electrolyte is a room temperature ionic liquid electrolyte.

12. The device of claim 11, wherein the room temperature ionic liquid electrolyte comprises 1-butyl, 3-methylimidazolium chloride ([BMIM][Cl]), 1-25% of cellulose and a lithium salt.

13. The device of claim 1, wherein the carbon nanotubes in the carbon nanotube layer are at least partially aligned in a direction, said direction being at least nearly perpendicular to the surface of the metal foil.

14. A process for forming a layer of carbon nanotubes on a flexible metal foil, comprising:
coating a catalyst on a surface of the metal foil by low temperature evaporation of the catalyst;
annealing the catalyst coated metal foil in ammonia gas at a first temperature; and
growing the carbon nanotubes directly on the catalyst coated surface of the metal foil in a hydrocarbon gas atmosphere at a second temperature, wherein the first temperature is lower than the second temperature and the second temperature is no higher than 550° C.

15. The process of claim 14, wherein the metal foil is one of the following: aluminum, copper, iron, and alloys of aluminum, copper or iron.

16. The process of claim 15, wherein the metal foil has a thickness of 5 to 100 microns.

17. The process of claim 14, wherein the catalyst comprises one of the following: iron, nickel and cobalt.

18. The process of claim 14, wherein the catalyst has a particle size of no more than 50 nanometers.

19. The process of claim 14, wherein the carbon nanotubes are grown to a length of 10 to 100 microns.

20. The process of claim 14, wherein the carbon nanotubes grown on the metal foil are at least partially aligned in a direction, said direction being at least nearly perpendicular to the surface of the metal foil.

21. The process of claim 14, wherein the process is carried out in a chemical vapor deposition system.

22. A method, comprising:
providing a first sheet of a conductive material;
disposing a sheet of a substance on the first sheet of the conductive material, the substance being able to conduct free ions therein; and
disposing a second sheet of same or different conductive material on the sheet of the substance, wherein at least one of the first sheet and the second sheet comprises a metal foil layer and a carbon nanotube layer, the carbon nanotube layer being arranged to face the sheet of the substance, and wherein the carbon nanotube layer is directly grown on the metal foil layer.

23. The method of claim 22, wherein the first sheet, the sheet of the substance and the second sheet form a multi-layered stack, and the method further comprises:
disposing a first insulating sheet and a second insulating sheet on outer surfaces of the multi-layered stack, respectively.

24. The method of claim 23, wherein the multi-layered stack has much larger width and length than thickness, and the method further comprises:
rolling up or folding the multi-layered stack; and
hermetically sealing the rolled-up or folded multi-layered stack to form an energy storage unit.

25. The method of claim 24, wherein the energy storage unit is a rechargeable battery or a capacitor, and the method further comprises:
connecting the first and the second conductive sheets with an external energy source or drain.

26. The method of claim 22, wherein the carbon nanotube layer is grown directly on the metal foil layer by a process that comprises:
coating a catalyst on a surface of the metal foil by low temperature evaporation of the catalyst;
annealing the catalyst coated metal foil in ammonia gas at a first temperature; and
growing the carbon nanotubes directly on the catalyst coated surface of the metal foil in a hydrocarbon gas atmosphere at a second temperature, wherein the first temperature is lower than the second temperature and the second temperature is no higher than 550° C.

27. The method of claim 26, wherein the process for growing the carbon nanotube layer is carried out in a chemical vapor deposition system.
